(19) United States
(12) Patent Application Publication
(10) Pub. No.: US 2012/0061880 A1
(43) Pub. Date: Mar. 15, 2012

(54) MOLDING APPARATUS AND MOLDING METHOD FOR PACKAGING SEMICONDUCTOR

(76) Inventor: Seok-Jae Han, Seoul (KR)

(21) Appl. No.: 13/221,576

(22) Filed: Aug. 30, 2011

(30) Foreign Application Priority Data
Sep. 15, 2010 (KR) 10-2010-0090536

(51) Int. Cl. H01L 21/56; B29C 45/00; B29C 45/76; B29C 45/14

(52) U.S. Cl. 264/443; 264/272.17; 425/129.1; 425/174.2

(57) ABSTRACT

A molding apparatus for packaging a semiconductor device includes an upper mold having a first cavity, a lower mold having a second cavity corresponding to the first cavity, and a selective flow facilitation unit. The first and second cavities are configured to receive a printed circuit board (PCB). The selective flow facilitation unit is configured to increase a flow of a molding resin in a selective area of the PCB. The flow of the molding resin in the selective area of the PCB is faster than the flow of the molding resin in a non-selective area of the PCB.

### CROSS-REFERENCE TO RELATED APPLICATIONS

This application claims priority under 35 U.S.C. §119 to Korean Patent Application No. 10-2010-0090536, filed on Sep. 15, 2010, the disclosure of which is incorporated by reference herein in its entirety.

### BACKGROUND

1. Technical Field

The inventive concept relates to a molding apparatus for packaging a semiconductor device, and more particularly, to a molding apparatus for packaging a semiconductor device which may improve the flowability of molding resin in a molding process.

2. Discussion of the Related Art

An integrated circuit including a chip on a semiconductor wafer undergoes a series of packaging processes. One of these packaging processes is a molding process.

In the molding process, the outside of a semiconductor chip and wires connected to the semiconductor chip are molded using a molding resin such as, for example, an epoxy molding compound (EMC). The molding process may be referred to as an encapsulation process.

According to a method for molding a semiconductor package, molding resin is injected at a constant pressure into a mold having a cavity configured to receive a printed circuit board (PCB), which includes an attached semiconductor chip. Since the injection of the molding resin relies only on injection pressure, an incomplete void (e.g., a space that is not filled with the molding resin) may be generated, resulting in molding defects.

An ultrasonic transducer may be attached to an outer wall of the mold to generate ultrasonic vibrations in the mold. This may improve the flowability of the molding resin by generating vibrations in all of the molding resin, however, incomplete voids may still be generated. For example, even when vibrations are generated in all of the molding resin, the flowability of the molding resin may decrease in areas of the PCB where a large number of NAND stacks exists, generating incomplete voids and resulting in molding defects.

### SUMMARY

Exemplary embodiments of the inventive concept provide a molding apparatus for packaging a semiconductor device which may improve the overall flowability of molding resin by improving flowability of molding resin in a local area having poor flowability, which may remove incomplete voids in the molding.

According to an exemplary embodiment of the inventive concept, a molding apparatus for packaging a semiconductor device includes an upper mold having a first cavity, a lower mold having a second cavity, and a selective flow facilitation unit. The first and second cavities are configured to receive a printed circuit board (PCB). The selective flow facilitation unit is configured to increase a flow of a molding resin in a selective area of the PCB. The flow of the molding resin in the selective area is faster than the flow of the molding resin in a non-selective area of the PCB.

The selective flow facilitation unit may include an ultrasonic transducer having an ultrasonic wave oscillation unit that generate ultrasonic waves, and an ultrasonic wave receiving unit that receives the ultrasonic waves.

The ultrasonic wave oscillation unit may include a pair of ultrasonic wave oscillators arranged near each other and adjusting a direction in which pressure is applied to the molding resin in the selective area.

At least a portion of the ultrasonic wave oscillator may contact the molding resin to generate vibrations directly in the molding resin.

The ultrasonic wave oscillator may be disposed in one of the upper or lower molds to apply pressure to the molding resin in a direction in which the molding resin flows.

The molding apparatus may include a ram coupled to one of the upper or lower molds configured to supply the molding resin to an area between the upper mold and the lower mold.

A heater for phase-shifting solid molding resin into liquid molding resin may be provided in least one of the upper mold and the lower mold, and the molding resin may be epoxy molding compound (EMC).

The ultrasonic transducer may be arranged at a position of the upper mold such that it partially contacts the liquid molding resin.

The ultrasonic wave oscillation unit may be provided in a first groove of a first protruding portion that is adjacent to the first cavity, and an ultrasonic wave receiving unit may be provided in a second groove of a second protruding portion located at the opposite side of the first protruding portion, with the first cavity interposed therebetween.

The selective area may be an area that includes a large number of NAND stacks.

According to an exemplary embodiment of the inventive concept, a molding apparatus for packaging a semiconductor device includes a molding mold having at least one cavity in which a PCB having a semiconductor chip attached thereto is received, and to the inside of which molding resin molded around the PCB to protect the semiconductor chip on the PCB is provided. The molding apparatus may further include a flow direction direct pressing unit provided in the molding mold and applying pressure directly to the molding mold in a direction in which the molding resin flows.

The flow direction direct pressing unit may be an ultrasonic transducer having a plurality of ultrasonic wave oscillation units that generate ultrasonic waves.

Each of the plurality of ultrasonic wave oscillation units may include a pair of ultrasonic wave oscillators arranged near each other.

The molding mold may include an upper mold having a first cavity, a lower mold driven to relatively move towards or away from the upper mold and having a second cavity at a position corresponding to the first cavity, and a ram coupled to the lower mold capable of being relatively moved and transferring the molding resin to a center area of the upper mold and the lower mold.

A heater for phase-shifting solid molding resin into liquid molding resin may be provided in at least one of the upper mold and the lower mold, and the molding resin may be EMC.

The ultrasonic transducer may be arranged at a position of the upper mold such that it partially contacts the liquid molding resin.

Each of the plurality of ultrasonic wave oscillation units may be provided in a first groove of a first protruding portion that is adjacent to the first cavity, and an ultrasonic wave receiving unit may be provided in a second groove of a second protruding portion located at the opposite side of the first protruding portion with the first cavity interposed therebetween.

According to an exemplary embodiment of the inventive concept, a molding method for packaging a semiconductor device includes receiving a PCB having a semiconductor chip attached thereto in a molding mold to the inside of which molding resin molded around the PCB is provided to protect the semiconductor chip on the PCB, and performing molding while making flow of a selective area needing facilitation of flow of the molding resin faster than that of a non-selective area other than the selective area.

The flow in the selective area may be made faster than that of the non-selective area by applying ultrasonic vibrations to the selective area.

The molding process may be performed as an ultrasonic transducer contacts the molding resin and generates ultrasonic vibrations directly to the molding resin.

The molding process may be performed as the ultrasonic vibrations are generated in the molding resin to apply pressure in a direction in which the molding resin flows.

The selective area may be an area having a large number of NAND stacks.

According to an exemplary embodiment of the inventive concept, a molding method for packaging a semiconductor device includes receiving a PCB having a semiconductor chip attached thereto in a molding mold to the inside of which molding resin molded around the PCB is provided to protect the semiconductor chip on the PCB, and performing molding while applying pressure directly to the molding resin in a direction in which the molding resin flows.

The molding process may be performed while contacting the molding resin and generating ultrasonic vibrations in the direction in which the molding resin flows.

The molding process may be performed while making flow of a selective area needing facilitation of flow of the molding resin faster than that of a non-selective area other then the selective area.

According to an exemplary embodiment of the inventive concept, a selective flow facilitation unit for a molding apparatus includes an ultrasonic wave oscillation unit disposed in the molding apparatus and configured to generate an ultrasonic wave, and an ultrasonic wave receiving unit disposed in the molding apparatus and configured to receive the ultrasonic wave. The ultrasonic wave is applied directly to a molding resin in a selective area of a PCB in a direction in which the molding resin flows.

The selective flow facilitation unit may include a first groove disposed adjacent to a first side of a cavity in the molding apparatus, and a second groove disposed adjacent to a second side of the cavity in the molding apparatus. The ultrasonic wave oscillation unit is disposed in the first groove, the ultrasonic wave receiving unit is disposed in the second groove, the second side of the cavity opposes the first side of the cavity, and the PCB is received into the cavity.

The ultrasonic wave oscillation unit may include a pair of ultrasonic wave oscillators configured to adjust a direction in which pressure is applied to the molding resin in the selective area of the PCB.

The ultrasonic wave oscillation unit may make contact with the molding resin.

According to an exemplary embodiment of the inventive concept, a molding method for packaging a semiconductor device includes receiving a PCB into a cavity disposed between an upper mold and a lower mold of a molding apparatus, and supplying a liquid molding resin to the PCB. A flow rate of the liquid molding resin supplied to a selective area of the PCB is faster than a flow rate of the liquid molding resin supplied to a non-selective area of the PCB.

The molding method may further include supplying a solid molding resin to an area between the upper mold and the lower mold, and phase-shifting the solid molding resin into the liquid molding resin.

The molding method may further include applying pressure directly to the liquid molding resin in a direction in which the liquid molding resin flows.

The pressure may be applied by generating an ultrasonic vibration directly in the liquid molding resin.

### BRIEF DESCRIPTION OF THE DRAWINGS

The above and other features of the present inventive concept will become more apparent by describing in detail exemplary embodiments thereof with reference to the accompanying drawings, in which:

FIGS. 1 and 2 illustrate a molding apparatus for packaging a semiconductor device, according to an exemplary embodiment of the present inventive concept;

FIGS. 3 and 4 are side views of a molding apparatus for packaging a semiconductor device, according to an exemplary embodiment of the present inventive concept;

FIGS. 5A-5C and 6 illustrate the flow rate of molding resin in a molding apparatus for packaging a semiconductor device, according to an exemplary embodiment of the present inventive concept;

FIGS. 7 and 8 illustrate a process in which molding resin is molded around a PCB in a molding apparatus for packaging a semiconductor device, according to an exemplary embodiment of the present inventive concept;

FIG. 9 shows the operation of an ultrasonic wave oscillation unit, according to an exemplary embodiment of the present inventive concept;

FIG. 10 is a flowchart illustrating a molding method for packaging a semiconductor device, according to an exemplary embodiment of the present inventive concept; and

FIGS. 11 and 12 are side views of a molding apparatus for packaging a semiconductor device, according to exemplary embodiments of the present inventive concept.

### DETAILED DESCRIPTION

Exemplary embodiments of the present inventive concept will be described more fully hereinafter with reference to the accompanying drawings. Like reference numerals may refer to like elements throughout the accompanying drawings.

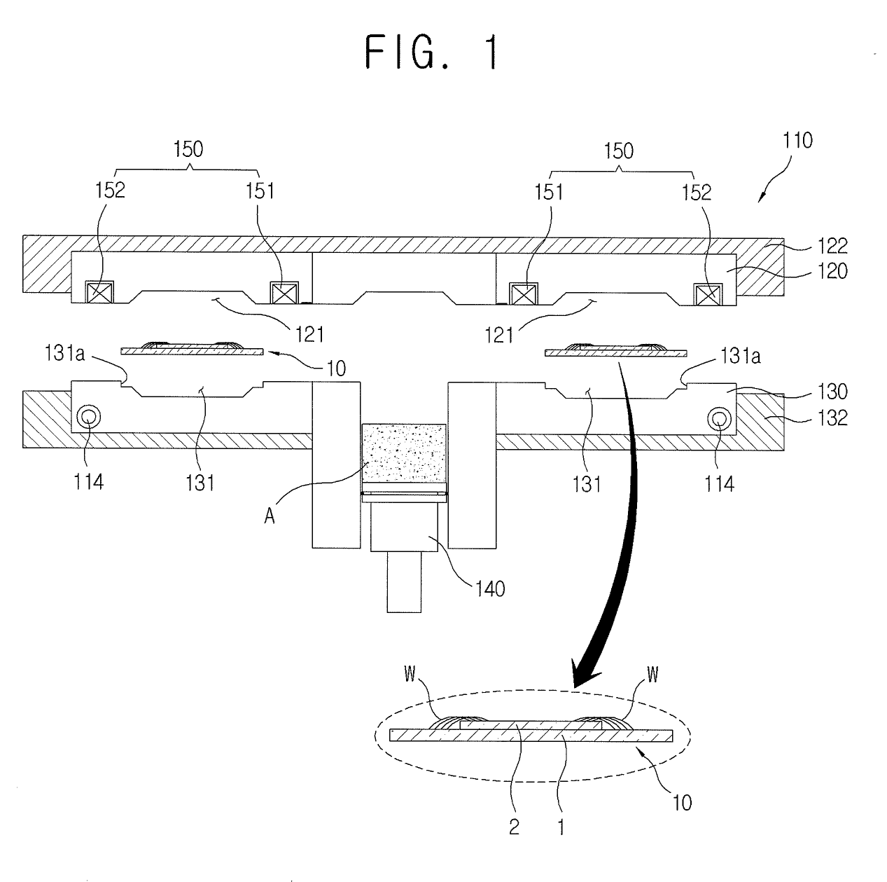

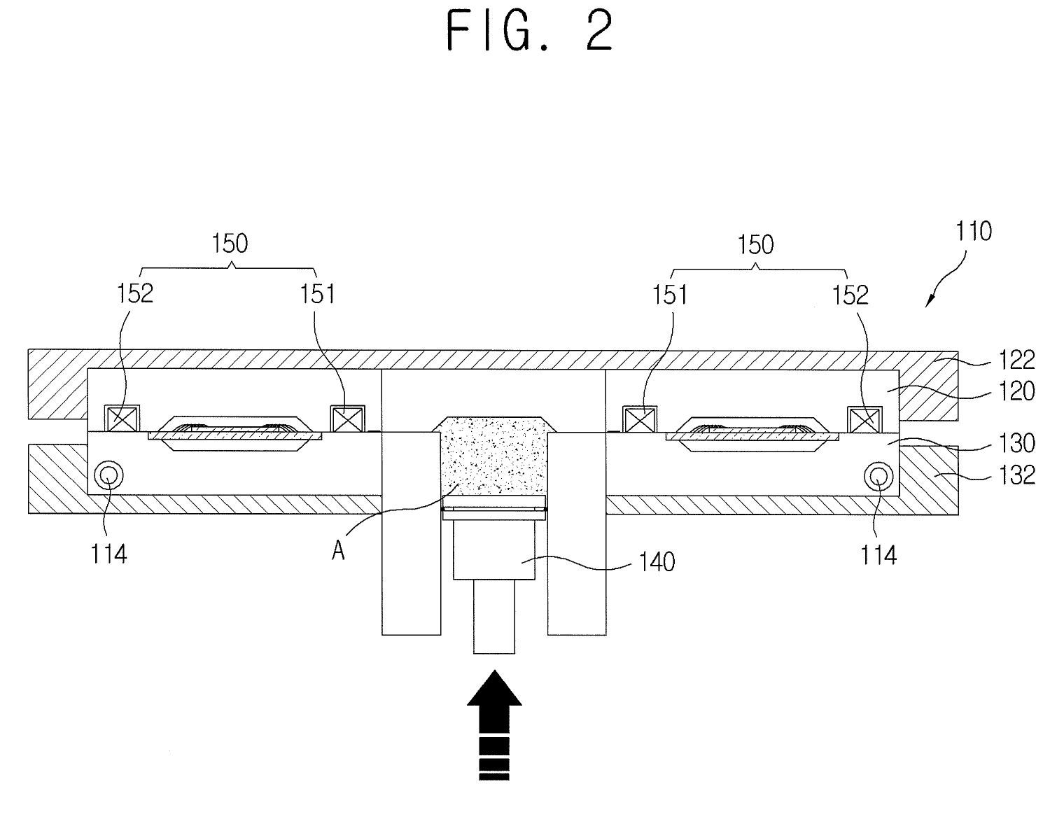

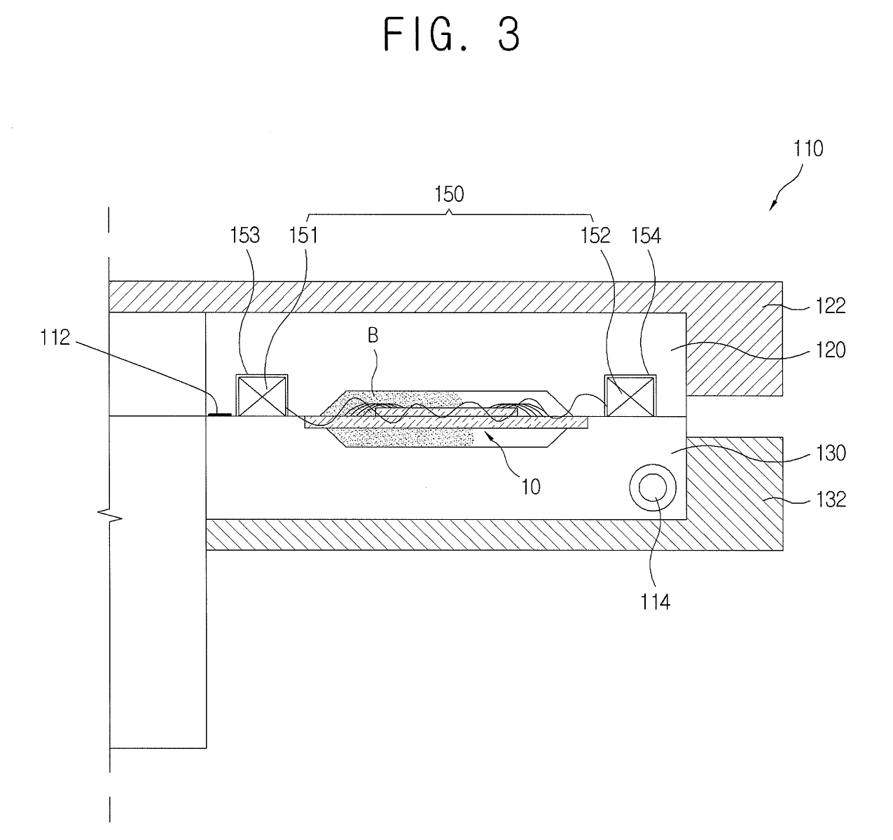

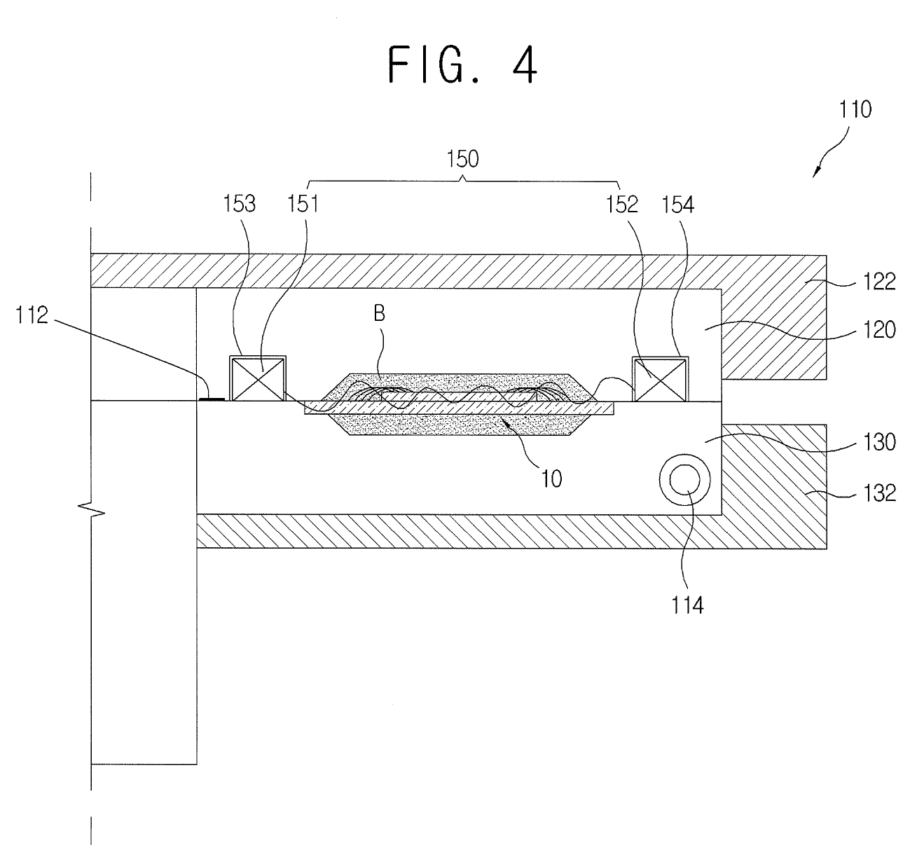

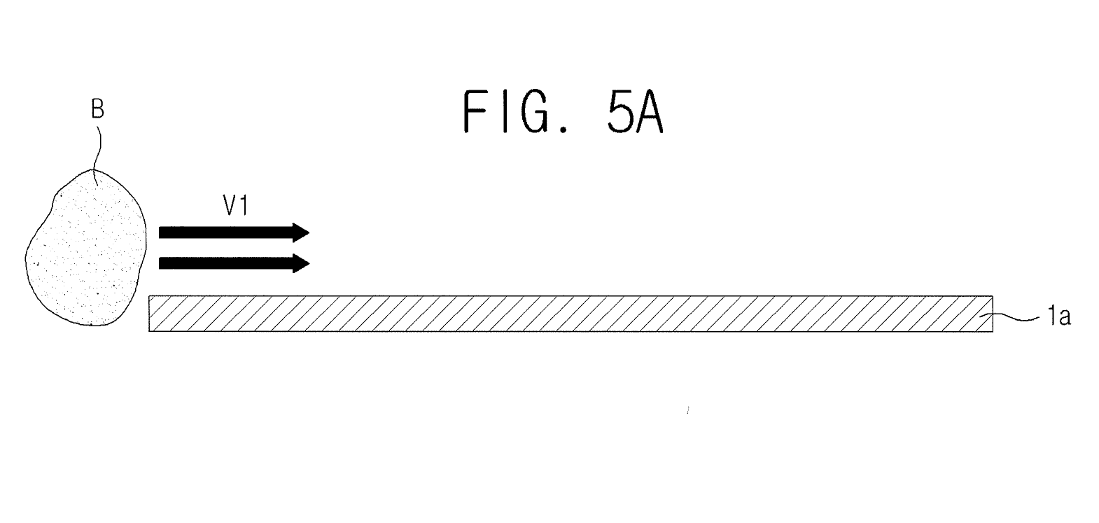

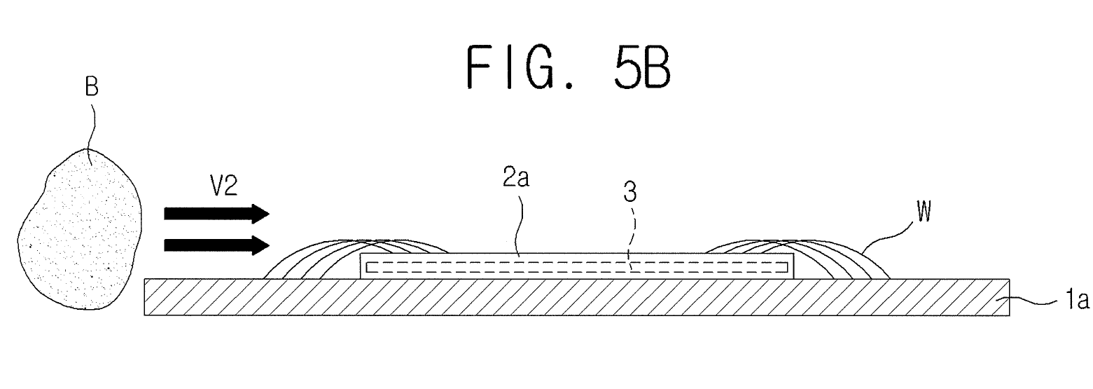

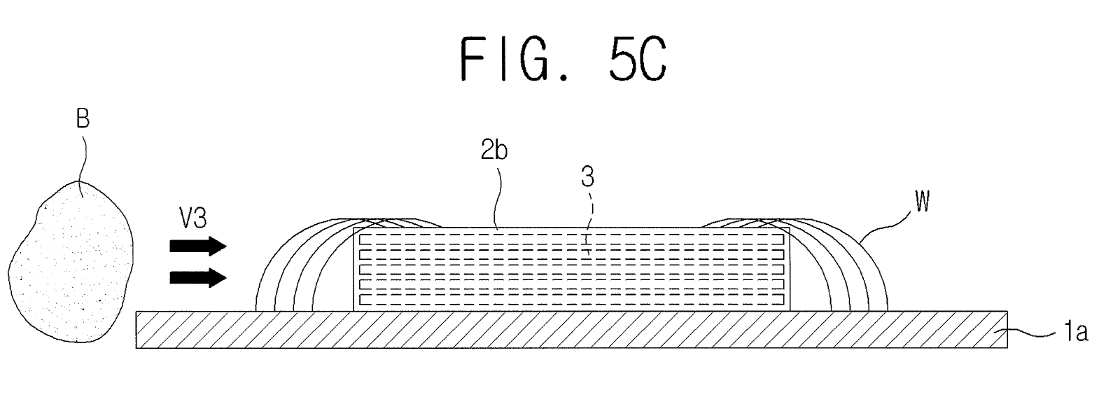

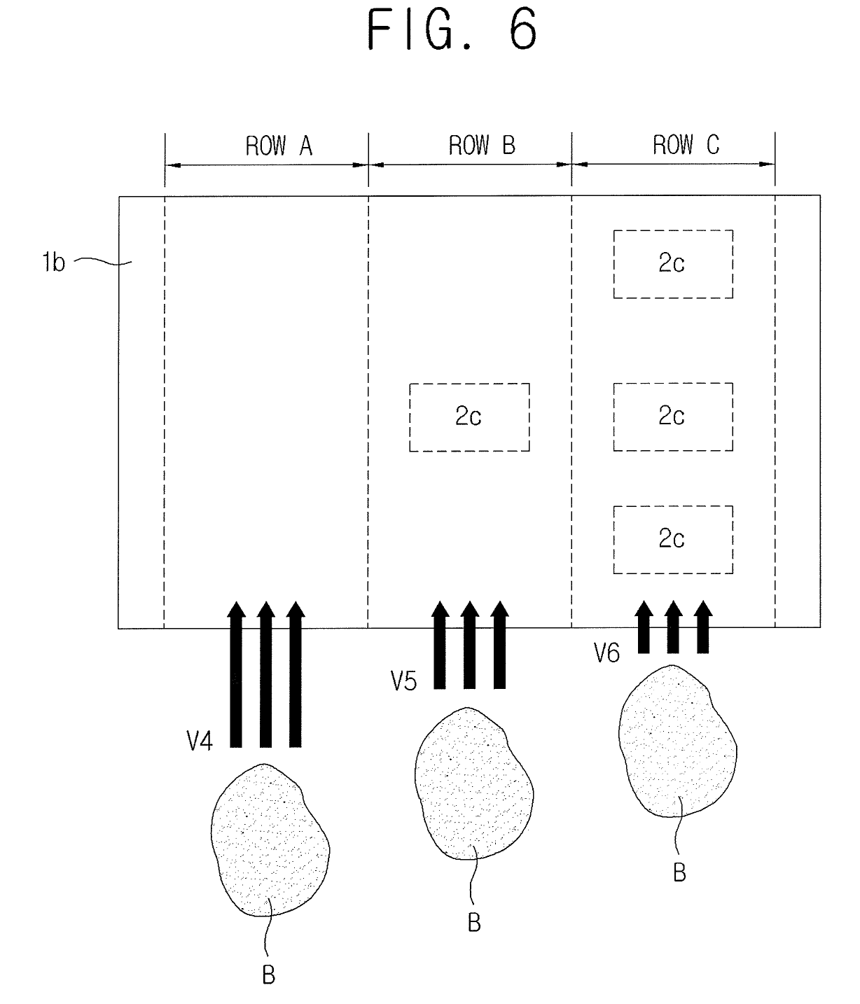

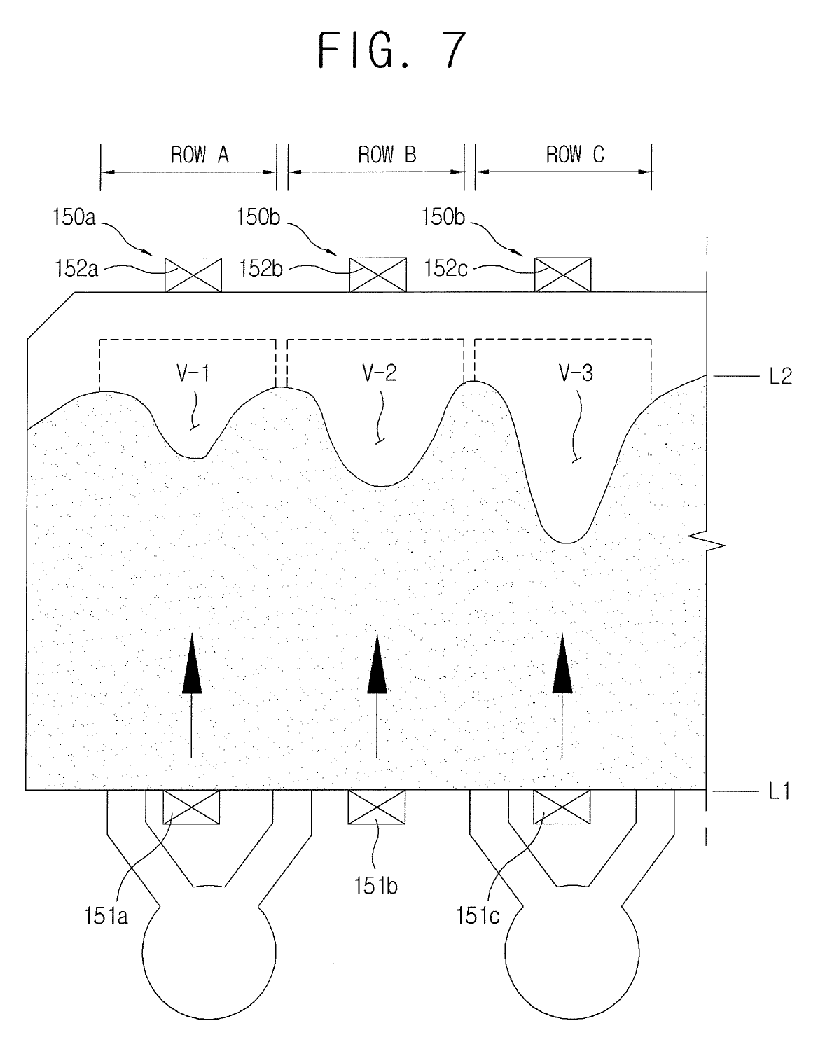

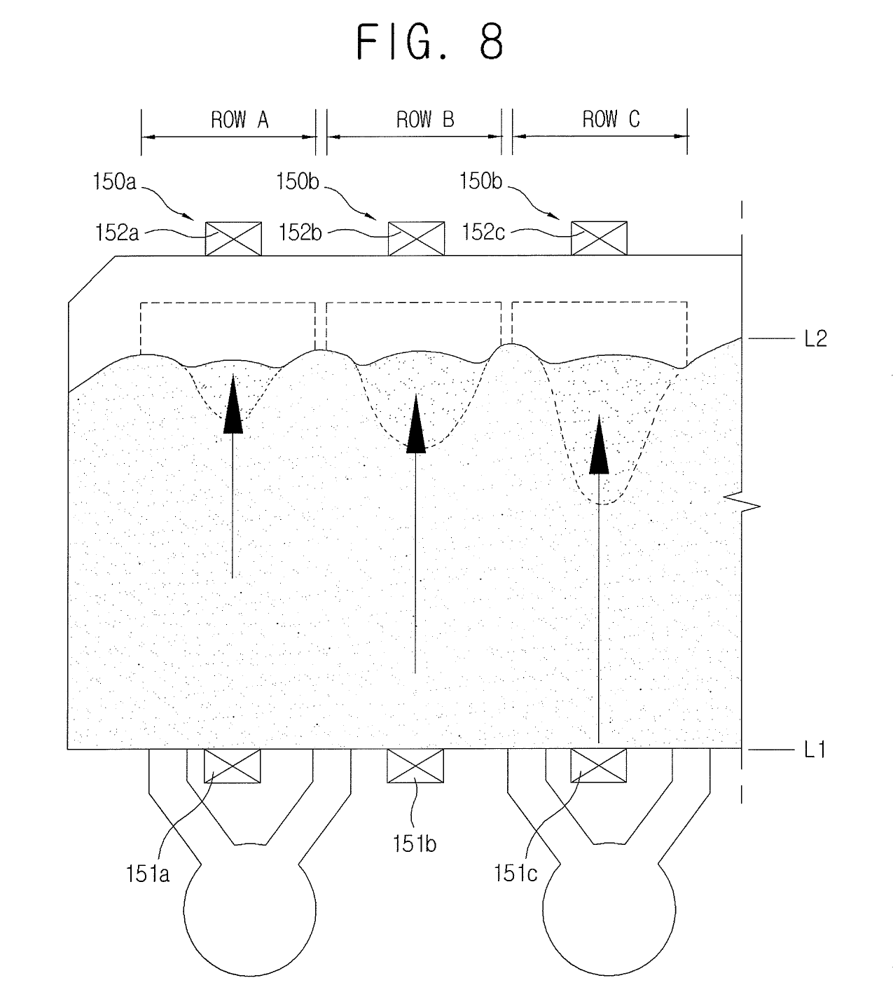

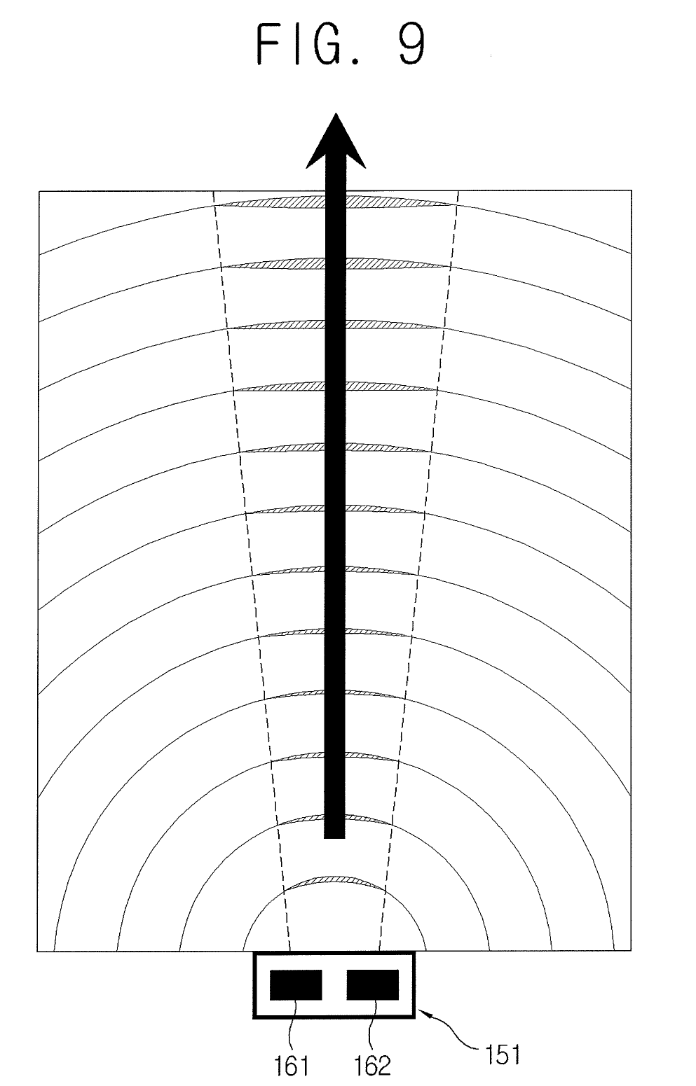

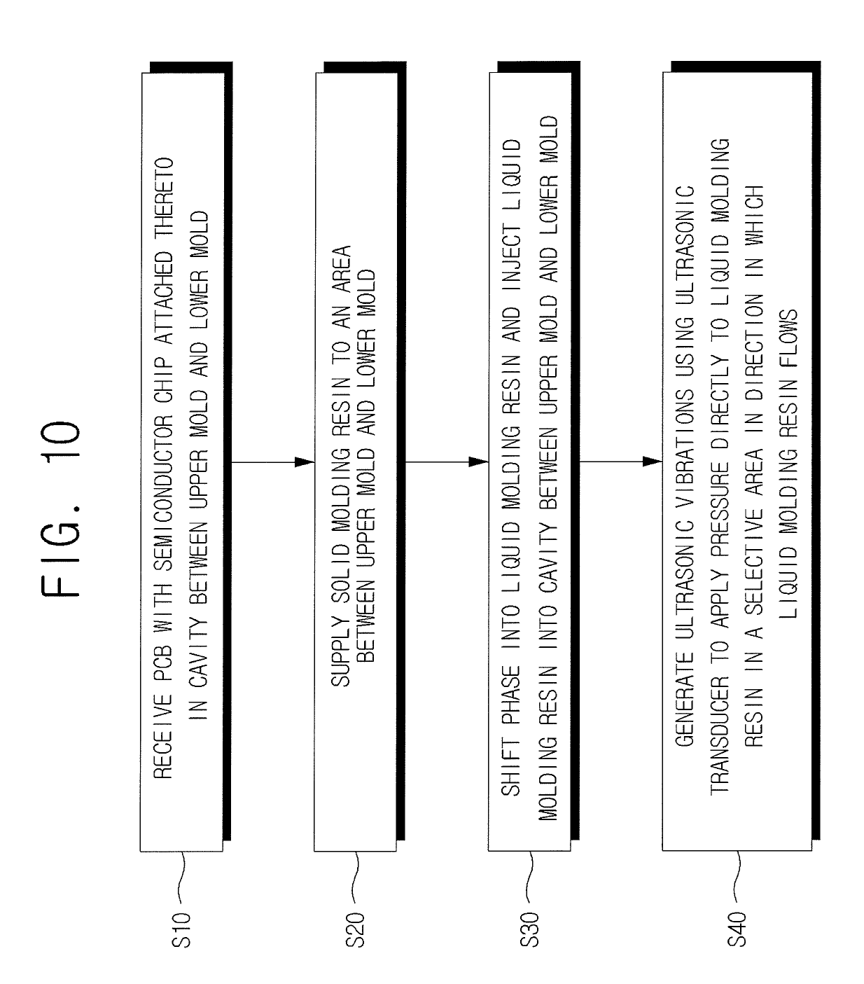

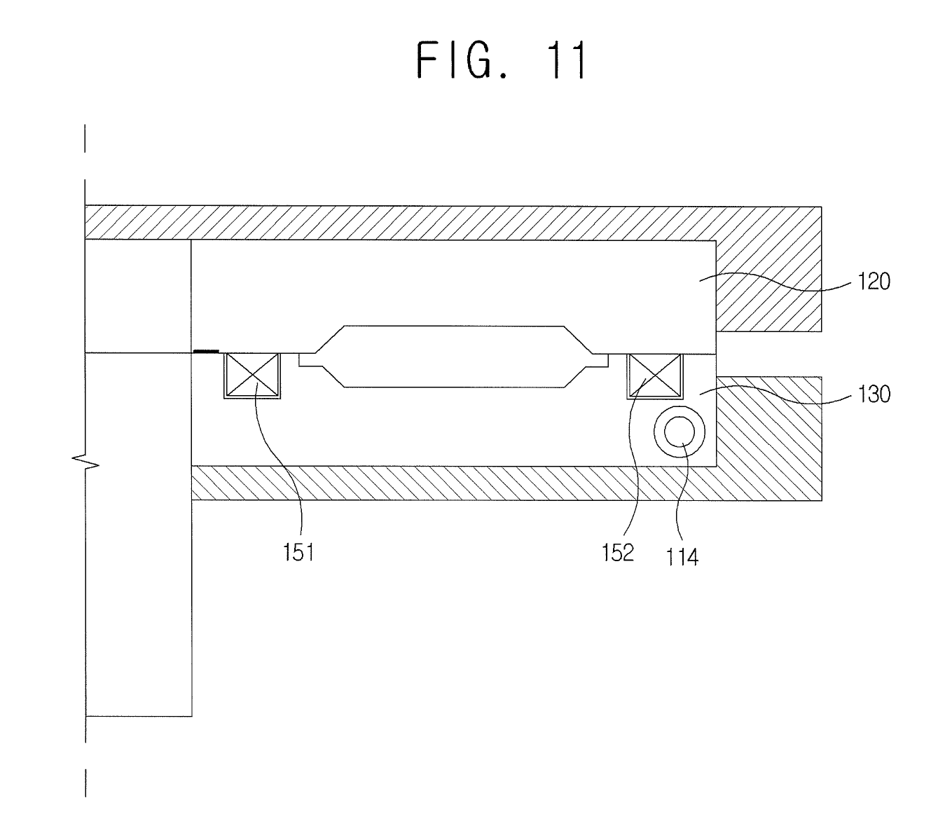

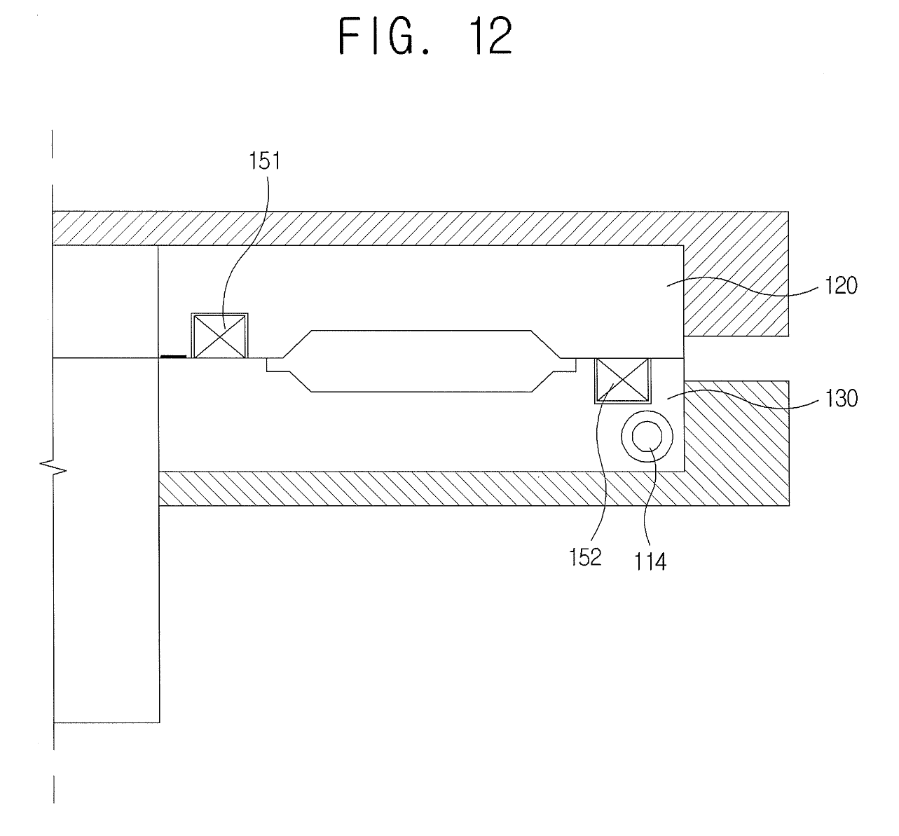

FIGS. 1 and 2 illustrate a molding apparatus for packaging a semiconductor device, according to an exemplary embodiment of the present inventive concept. FIGS. 3 and 4 are side views of a molding apparatus for packaging a semiconductor device, according to an exemplary embodiment of the present inventive concept. FIGS. 5A-5C and 6 illustrate the flow rate of molding resin in a molding apparatus for packaging a semiconductor device, according to an exemplary embodiment of the present inventive concept. FIGS. 7 and 8 illustrate a process in which molding resin is molded around a PCB in a molding apparatus for packaging a semiconductor device, according to an exemplary embodiment of the present inventive concept. FIG. 9 shows the operation of an ultrasonic wave oscillation unit, according to an exemplary embodiment of the present inventive concept. FIG. 10 is a flowchart illustrating a molding method for packaging a semiconductor device, according to an exemplary embodiment of the present inventive concept. FIGS. 11 and 12 are side views of a molding apparatus for packaging a semiconductor device, according to exemplary embodiments of the present inventive concept.

In an exemplary embodiment, a molding apparatus 110 for packaging a semiconductor device includes an upper mold 120 having a first cavity 121, a lower mold 130 having a second cavity 131, and a selective flow facilitation unit 150. The first and second cavities 121 and 131 are configured to receive a printed circuit board (PCB) 10. A semiconductor chip 2 is attached to the PCB 10. Molding resin is disposed around the PCB 10 to protect the semiconductor chip 2 mounted on the PCB 10. The selective flow facilitation unit 150 causes the flow of molding resin in a selective area to be faster than the flow of molding resin in a non-selective area (e.g., an area other than the selective area).

In an exemplary embodiment, the selective flow facilitation unit 150 is a flow direction direct pressing unit. The flow direction direct pressing unit applies pressure directly to molding resin in a direction in which the molding resin flows. As a result, the resin flow may be faster in a selective area than in a non-selective area. In another exemplary embodiment, the flow direction direct pressing unit applies pressure directly to all of the molding resin in the direction in which the molding resin flows without causing the resin flow in a selective area to be faster than the resin flow in a non-selective area. In another exemplary embodiment, the selective flow facilitation unit 150 causes the resin flow in a selective area to be faster than the resin flow in a non-selective area without directly applying pressure to the molding resin in the direction in which the molding resin flows.

The molding apparatus 110 is used to perform a molding process on the PCB 10 including the semiconductor chip 2. The semiconductor chip 2 is mounted on a lead frame 1 by wires W. The molding apparatus 110 may have a variety of shapes and structures, and the shape and structure is not limited to the exemplary embodiment illustrated in FIGS. 1 and 2.

The molding apparatus 110 includes an upper mold 120 having a first cavity 121, a lower mold 130 having a second cavity 131 corresponding to the first cavity 121, and a ram 140. An upper area of the PCB 10 is located in the first cavity 121. The lower mold 130 is driven to move towards or away from the upper mold 120. The ram 140 is coupled to the lower mold 130, and is capable of relatively moving with respect to the lower mold 130 and supplying a solid molding resin A to an area between the upper mold 120 and the lower mold 130.

The upper mold 120 and the lower mold 130 have a substantially similar structure. When the upper mold 120 and the lower mold 130 are separated from each other as illustrated in FIG. 1, the PCB 10 to be molded is arranged between the first cavity 121 and the second cavity 131. The molding resin is supplied to the PCB 10 during the molding process when the upper mold 120 and the lower mold 130 make contact with each other, as illustrated in FIG. 2.

Thus, to perform the molding process, one of the upper mold 120 and the lower mold 130 moves towards or away from the other mold. For example, the molding process may be performed by fixing the lower mold 130 and moving the upper mold 120 towards or away from the lower mold 130. Conversely, the molding process may be performed by fixing the upper mold 120 and moving the lower mold 130 towards or away from the upper mold 120. Although FIGS. 1 and 2 illustrate an exemplary embodiment performing the molding process by fixing the upper mold 120 and moving the lower mold 130 towards or away from the upper mold 120, the present inventive concept is not limited thereto.

The lower mold 130 is moved towards or away from the upper mold 120 using a driving unit (not shown) coupled to the lower mold 130. The driving unit may be, for example, a cylinder, a linear motor, or a combination of a general motor and a ball screw, however the driving unit is not limited thereto.

In the exemplary embodiment shown in FIG. 1, a fitting groove 131a is formed in the second cavity 131. The lead frame 1 of the PCB 10 is partially inserted into the fitting groove 131a so that the PCB 10 may be seated in the space between the first and second cavities 121 and 131. In an exemplary embodiment, the fitting groove 131a may be provided at the first cavity 121 of the upper mold 120.

In an exemplary embodiment, an upper exterior frame 122 is coupled to the outside of the upper mold 120 and a lower exterior frame 132 is coupled to the outside of the lower mold 130. In another exemplary embodiment, the upper exterior frame 122 and the lower exterior frame 132 are not included.

As shown in FIGS. 3 and 4, a plurality of runners 112 are provided in the upper mold 120. The plurality of runners 112 allow for the flowing of liquid molding resin B. In another exemplary embodiment, the runners 112 are provided in the lower mold 130. The ram 140 disposed in a central area of the lower mold 130 pushes the solid molding resin A upward towards an area between the upper mold 120 and the lower mold 130 during the molding process.

In an exemplary embodiment, the molding apparatus 110 pushes the solid molding resin A upward towards an area between the upper mold 120 and the lower mold 130 and liquidizes the solid molding resin A, causing the liquid molding resin B to flow, thereby performing the molding process.

In an exemplary embodiment, the molding apparatus 110 includes a heater 114 for phase-shifting the solid molding resin A into the liquid molding resin B. In FIGS. 1-4, the heater 114 is provided in the lower mold 130 and melts the solid molding resin A, resulting in the formation of the liquid molding resin B. In other exemplary embodiments, the heater 114 may be provided in the upper mold 120, or in both the upper mold 120 and the lower mold 130.

The molding resin may be formed of various materials including, but not limited to, epoxy molding compound (EMC). For example, when the molding resin is EMC, the solid molding resin A shown in FIGS. 1 and 2 is EMC in a solid state, and the liquid molding resin B shown in FIGS. 3 and 4 is EMC that is melted into a liquid state.

The molding resin protects the PCB 10 from the external environment (e.g., external shocks, vibrations, moisture, or radiation), provides electrical insulation from the external environment, effectively emits heat generated during the operation of a device, and facilitates surface mounting. The PCB may be used to form, for example, an integrated circuit (IC), a large scale integration (LSI) IC, or a very large scale integration (VLSI) IC.

The utilization of molding resin such as, for example, EMC accounts for a large portion of the semiconductor manufacturing process.

As shown in FIGS. 3 and 4, the selective flow facilitation unit 150 causes the molding resin to flow in a selective area of the PCB 10 where the flow of molding resin is slow. The flow of molding resin may be slow in certain areas of the PCB 10 due to, for example, certain structural characteristics of the PCB 10. For example, the flow of molding resin may be slow in an area having a large number of NAND stacks. The selective flow facilitation unit 150 may be used to cause the flow of molding resin in such an area to be faster than the flow of molding resin in a non-selective area (e.g., an area other than the selective area). The selective area corresponds to an area (or a plurality of areas) where it is determined that the resin flow should be made faster. The selective area is not limited to an area where the resin flow is the slowest.

Rather than generating vibrations in all of the molding resin by generating ultrasonic vibrations in the upper mold 120 and/or the lower mold 130, the selective flow facilitation unit 150 may locally or selectively improve the flowability of a specific portion of the molding resin where the flowability is poor. Accordingly, molding defects caused by the generation of incomplete voids (e.g., spaces that do not receive molding resin) may be reduced.

In an exemplary embodiment, the selective flow facilitation unit 150 functions as a flow direction direct pressing unit. The flow direction direct pressing unit applies pressure directly to molding resin in a direction in which the molding resin flows. Since pressure is applied directly to the molding resin in a direction in which the molding resin flows rather than being applied indirectly to the molding resin via ultrasonic vibrations generated in the upper mold 120 and/or the lower mold 130, the flowability of the molding resin may be improved.

In an exemplary embodiment, the selective flow facilitation unit 150 is an ultrasonic transducer 150. The ultrasonic transducer 150 may be classified as, for example, a magnetostrictive type transducer, a piezoelectric/electrostrictive type transducer, or an electronic type transducer. In an exemplary embodiment, a bolt-clamped langevin transducer (BLT), which is classified as a piezoelectric/electrostrictive type transducer, is employed.

The ultrasonic transducer generates ultrasonic vibrations by directly contacting molding resin in a direction in which the molding resin (e.g., EMC) flows toward the PCB 10 to be molded. For example, when the selective flow facilitation unit 150 shown in FIGS. 3 and 4 is an ultrasonic transducer, it is provided inside the molding apparatus 110 to partially contact the molding resin.

As shown in FIGS. 1-4, when the selective flow facilitation unit 150 is an ultrasonic transducer, it includes an ultrasonic wave oscillation unit 151 and an ultrasonic wave receiving unit 152 arranged separately from the ultrasonic wave oscillation unit. The ultrasonic wave oscillation unit 151 oscillates ultrasonic waves, and the ultrasonic wave receiving unit 152 receives the ultrasonic waves oscillated by the ultrasonic wave oscillation unit 151. The ultrasonic transducer generates and supplies ultrasonic vibrations directly to the molding resin (e.g., EMC), which acts as a medium.

In an exemplary embodiment, the ultrasonic transducer is provided in the upper mold 120 such that it partially contacts the molding resin (e.g., EMC), as shown in FIGS. 1-4. In another exemplary embodiment, the ultrasonic transducer is provided in the lower mold 130.

When the ultrasonic transducer is provided in the upper mold 120, the ultrasonic wave oscillation unit 151 is provided in a first groove 153 disposed near the first cavity 121, and the ultrasonic wave receiving unit 152 is provided in a second groove 154 at the opposite side of the first cavity 121.

In an exemplary embodiment, the ultrasonic wave oscillation unit 151 and the ultrasonic wave receiving unit 152 are forcibly inserted into the first groove 153 and the second groove 154, respectively. In another exemplary embodiment, the ultrasonic wave oscillation unit 151 and the ultrasonic wave receiving unit 152 are detachably installed in the first groove 153 and the second groove 154, respectively, in the form of a kit. The first groove 153 and the second groove 154 may be large enough to allow the ultrasonic wave oscillation unit 151 and the ultrasonic wave receiving unit 152 to be respectively seated in the first groove 153 and the second groove 154. An additional stopper (not shown) provided in each of the first groove 153 and the second groove 154 may be used to adjust the respective positions of the ultrasonic wave oscillation unit 151 and the ultrasonic wave receiving unit 152.

As illustrated in FIG. 9, in an exemplary embodiment, the ultrasonic wave oscillation unit 151 of the ultrasonic transducer includes a pair of ultrasonic oscillators 161 and 162 arranged near each other and configured to adjust a direction in which pressure is applied to the molding resin in the selective area of the PCB 10. The pair of ultrasonic oscillators 161 and 162 allow the cycle, amplitude, phase, and vibration direction of a waveform to be adjusted using constructive interference and destructive interference. Referring to constructive interference, phases of two waves are reinforced when a ridge of one wave is superimposed on a ridge of the other wave. Referring to destructive interference, phases of two waves are offset when a ridge of one wave is superimposed on a trough of the other wave. Accordingly, ultrasonic vibrations are generated such that pressure can be applied only in the selective area in a direction in which the molding resin flows. As a result, the flowability of the molding resin in the selective area may be improved.

In an exemplary embodiment, the flow rate of the molding resin B (e.g., EMC) is V1 when no chip and wires are present on a lead frame 1a, as illustrated in FIG. 5A. The flow rate of the molding resin B is V2 when a first chip 2a is mounted by wires W on the lead frame 1a, as illustrated in FIG. 5B. Since the first chip 2a protruding from the lead frame 1a disturbs the flow rate of the molding resin B, V2 is slower than V1. The flow rate of the molding resin B is V3 when a second chip 2b having a height higher than the height of the first chip 2a is mounted on the lead frame 1a, as illustrated in FIG. 5C. The second chip 2b has a height higher than the height of the first chip 2a because the number of NAND stacks 3 in the second chip 2b is greater than the number of NAND stacks 3 in the first chip 2a. Since the second chip 2b protruding from the lead frame 1a further disturbs the flow rate of the molding resin B, V3 is slower than V2.

There are a number of factors that can cause molding defects. For example, when the flow rate of the molding resin decreases, the direction of resin flow may change and the molding process may not be properly performed. As a result, even when the amount and flow rate of the molding resin is consistent, the molding process may not be timely completed, which can result in voids (e.g., spaces or areas) that do not receive the molding resin.

Referring to FIG. 6, molding resin B flows in directions along rows A, B, and C on a lead frame 1b. The flow rate V4 of molding resin flowing in row A is the fastest flow rate since no chip or wires are disposed in row A. The flow rate V5 of molding resin flowing in row B is slower than the flow rate V4 since one chip 2c is disposed in row B. The flow rate V6 of molding resin flowing in row C is slower than the flow rates V4 and V5 since a plurality of chips 2c are disposed in row C. In FIG. 6, it is assumed that each of the chips 2c includes an equal number of NAND stacks 3. Increasing the number of NAND stacks 3 on any of the chips 2c may decrease the flow rate in the row corresponding to that respective chip 2c.

As described above, as more chips 2c are arranged in a path where the molding resin flows, the flow rate of the molding resin becomes more disturbed. For example, in row C in FIG. 6, because there are a number of chips 2c decreasing the flow rate of the molding resin, a molding process may not be completed within a set time period, and incomplete voids may be generated, which may cause molding defects.

Referring to FIGS. 5B and 5C and rows B and C in FIG. 6, rather than indirectly generating vibrations in the molding resin by generating ultrasonic vibrations in the upper mold 120 and the lower mold 130, applying pressure directly to the molding resin in the direction the molding resin flows may decrease the generation of incomplete voids, and thus, decrease molding defects.

For example, the flowability is locally poor in the areas shown in FIGS. 5B and 5C and rows B and C in FIG. 6 due to the structural characteristics of the areas (e.g., the presence of chips 2c). The ultrasonic transducer may generate ultrasonic vibrations directly in the molding resin in these areas (e.g., the selective areas) using interference, as described above. This results in pressure being applied in a direction in which the molding resin flows, which may decrease the generation of incomplete voids, and thus, decrease molding defects.

A molding method of packaging a semiconductor device according to an exemplary embodiment is described with reference to FIGS. 1, 2, 7, and 10. When the upper mold 120 and the lower mold 130 are separated from each other as illustrated in FIG. 1, the PCB 10 to be molded is received in the first and second cavities 121 and 131 of the upper mold 120 and the lower mold 130 (S10). The upper mold 120 and the lower mold 130 make contact with each other as illustrated in FIG. 2, and a solid molding resin A is moved by the ram 140 and supplied to an area between the upper mold 120 and the lower mold 130 (S20).

The solid molding resin A disposed between the upper mold 120 and the lower mold 130 is phase-shifted by the heater 114 into a liquid molding resin B (S30). The liquid molding resin B flows towards the first and second cavities 121 and 131 via a passage (e.g., runners 112), and is molded around the PCB 10. Ultrasonic vibrations are generated using an ultrasonic transducer to apply pressure directly to the liquid molding resin B in a selective area in the direction in which the liquid molding resin B flows (S40).

Referring to FIGS. 7 and 8, in an exemplary embodiment, a molding process is performed from a position L1 to a position L2. First to third ultrasonic transducers 150a-150c each include one of ultrasonic wave oscillation units 151a-151c and one of ultrasonic wave receiving units 152a-152c, respectively. As shown in FIG. 7, incomplete voids V-1, V-2, and V-3 are generated in middle areas of rows A, B, and C due to factors that disturb the flowability of the molding resin (e.g., factors may include the number of NAND stacks 3, as described with reference to FIG. 5). The ultrasonic transducers 150a-150c generate vibrations by adjusting the cycle, amplitude, phase, and vibration direction of a waveform using interference, as described above. The vibrations are generated directly in the molding resin by applying pressure in the direction in which the molding resin flows. As a result, the flowability of the molding resin in the middle areas of the rows A, B, and C may increase (e.g., the molding resin may flow faster). For example, the flowability of the molding resin in row C is faster than the flowability of the molding resin in row B, and the flowability of the molding resin in row B is faster than the flowability of the molding resin in row A. As a result, incomplete voids V-1, V-2 and V-3 may be substantially removed, as illustrated in FIG. 8.

FIGS. 11 and 12 are side views of a molding apparatus for packaging a semiconductor device according to exemplary embodiments of the present inventive concept.

FIG. 11 illustrates an exemplary embodiment in which the ultrasonic wave oscillation unit 151 and the ultrasonic wave receiving unit 152 are both disposed in the lower mold 130. FIG. 12 illustrates an exemplary embodiment in which the ultrasonic wave oscillation unit 151 is disposed in the upper mold 120 and the ultrasonic wave receiving unit 152 is disposed in the lower mold 130.

As described above, according to exemplary embodiments of the present inventive concept, the overall flowability of molding resin may be improved by improving the flowability of molding resin in a local area where the flowability of molding resin is poor. The flowability of molding resin may be improved by applying pressure directly to the molding resin in a selective area in a direction in which the molding resin flows. As a result, the generation of incomplete voids may be reduced, thus, reducing molding defects.

While the present inventive concept has been particularly shown and described with reference to the exemplary embodiments thereof, it will be understood by those of ordinary skill in the art that various changes in form and detail may be made therein without departing from the spirit and scope of the present inventive concept as defined by the following claims.

What is claimed is:

1. A molding apparatus, comprising:
an upper mold having a first cavity;
a lower mold having a second cavity corresponding to the first cavity, wherein the first and second cavities are configured to receive a printed circuit board (PCB); and
a selective flow facilitation unit configured to increase a flow of a molding resin in a selective area of the PCB, wherein the flow of the molding resin in the selective area is faster than the flow of the molding resin in a non-selective area of the PCB.

2. The molding apparatus of claim 1, wherein the selective flow facilitation unit comprises:
an ultrasonic transducer having an ultrasonic wave oscillation unit configured to generate an ultrasonic wave, and an ultrasonic wave receiving unit configured to receive the ultrasonic wave.

3. The molding apparatus of claim 2, wherein the ultrasonic wave oscillation unit comprises:
a pair of ultrasonic wave oscillators configured to adjust a direction in which pressure is applied to the molding resin in the selective area.

4. The molding apparatus of claim 2, wherein at least a portion of the ultrasonic wave oscillator contacts the molding resin and generates a vibration directly in the molding resin.

5. The molding apparatus of claim 2, wherein the ultrasonic wave oscillator is configured to apply pressure to the molding resin in a direction in which the molding resin flows.

6. The molding apparatus of claim 2, further comprising:
a first groove disposed adjacent to a first side of the first cavity and configured to receive the ultrasonic wave oscillation unit; and
a second groove disposed adjacent to a second side of the first cavity and configured to receive the ultrasonic wave receiving unit, wherein the second side of the first cavity opposes the first side of the first cavity.

7. The molding apparatus of claim 1, further comprising:
a ram coupled to one of the upper mold or the lower mold, wherein the ram is configured to supply the molding resin to an area between the upper mold and the lower mold.

8. The molding apparatus of claim 1, further comprising:
a heater disposed in one of the upper mold or the lower mold, wherein the heater is configured to phase-shift a solid molding resin into a liquid molding resin.

9. The molding apparatus of claim 8, wherein an ultrasonic transducer is disposed in the upper mold and partially contacts the liquid molding resin.

10. The molding apparatus of claim 1, wherein the selective area includes a plurality of NAND stacks.

11. The molding apparatus of claim 1, wherein the molding resin comprises an epoxy molding compound (EMC).

12. The molding apparatus of claim 1, further comprising:
a plurality of runners disposed in one of the upper mold or the lower mold and configured to supply the molding resin to the PCB.

13. A selective flow facilitation unit for a molding apparatus, comprising:
an ultrasonic wave oscillation unit disposed in the molding apparatus and configured to generate an ultrasonic wave; and
an ultrasonic wave receiving unit disposed in the molding apparatus and configured to receive the ultrasonic wave,
wherein the ultrasonic wave is applied directly to a molding resin in a selective area of a printed circuit board (PCB) in a direction in which the molding resin flows.

14. The selective flow facilitation unit of claim 13, further comprising:
a first groove disposed adjacent to a first side of a cavity in the molding apparatus; and
a second groove disposed adjacent to a second side of the cavity in the molding apparatus,
wherein the ultrasonic wave oscillation unit is disposed in the first groove, the ultrasonic wave receiving unit is disposed in the second groove, the second side of the cavity opposes the first side of the cavity, and the PCB is received into the cavity.

15. The selective flow facilitation unit of claim 13, wherein the ultrasonic wave oscillation unit comprises:
a pair of ultrasonic wave oscillators configured to adjust a direction in which pressure is applied to the molding resin in the selective area of the PCB.

16. The selective flow facilitation unit of claim 13, wherein the ultrasonic wave oscillation unit makes contact with the molding resin.

17. A molding method for packaging a semiconductor device, comprising:
receiving a printed circuit board (PCB) into a cavity disposed between an upper mold and a lower mold of a molding apparatus; and
supplying a liquid molding resin to the PCB, wherein a flow rate of the liquid molding resin supplied to a selective area of the PCB is faster than a flow rate of the liquid molding resin supplied to a non-selective area of the PCB.

18. The molding method of claim 17, further comprising:
supplying a solid molding resin to an area between the upper mold and the lower mold; and
phase-shifting the solid molding resin into the liquid molding resin.

19. The molding method of claim 17, further comprising:
applying pressure directly to the liquid molding resin in a direction in which the liquid molding resin flows.

20. The molding method of claim 19, wherein the pressure is applied by generating an ultrasonic vibration directly in the liquid molding resin.
